(19) United States
(12) Patent Application Publication
(10) Pub. No.: US 2025/0311340 A1
(43) Pub. Date: Oct. 2, 2025

(54) NITRIDE-BASED SEMICONDUCTOR DEVICE AND METHOD FOR MANUFACTURING THE SAME

(71) Applicant: INNOSCIENCE (SUZHOU) SEMICONDUCTOR CO., LTD., Jiangsu (CN)

(72) Inventors: Peng-Yi WU, Jiangsu (CN); Chuangang LI, Jiangsu (CN); Yuanyu WU, Jiangsu (CN)

(73) Assignee: INNOSCIENCE (SUZHOU) SEMICONDUCTOR CO., LTD., Jiangsu (CN)

(21) Appl. No.: 18/864,897

(22) PCT Filed: May 12, 2022
(86) PCT No.: PCT/CN2022/092336

§ 371 Date: Nov. 12, 2024

(51) Int. Cl. H10D 62/60; H10D 30/01; H10D 30/47; H10D 62/10; H10D 62/824

(52) U.S. Cl. CPC H10D 62/60; H10D 30/015; H10D 30/471; H10D 62/102; H10D 62/124; H10D 62/824

(57) ABSTRACT

A semiconductor device includes a first III-V nitride-based layer, a second III-V nitride-based layer, a nitride-based semiconductor layer, and a nitride-based transistor. The first III-V nitride-based layer is disposed over a substrate by applying a first V/III ratio. The first III-V nitride-based layer has a first concentration of a group III element. The second III-V nitride-based layer is disposed on the first III-V nitride-based layer by applying a second V/III ratio less than the first V/III ratio. The second III-V nitride-based layer has a second concentration of the group III element less than the first concentration. The second concentration decreases along a direction away from the first III-V nitride-based layer, such that a first variance in the first concentration is less than a second variance in the second concentration. The nitride-based semiconductor layer is disposed over the second III-V nitride-based layer.

### FIELD OF THE DISCLOSURE

The present disclosure generally relates to a nitride-based semiconductor device. More specifically, the present disclosure relates to a nitride-based semiconductor device having a varied V/III ratio to improve epitaxial growth quality.

### BACKGROUND OF THE DISCLOSURE

In recent years, intense research on high-electron-mobility transistors (HEMTs) has been prevalent, particularly for high power switching and high frequency applications. III-nitride-based HEMTs utilize a heterojunction interface between two materials with different bandgaps to form a quantum well-like structure, which accommodates a two-dimensional electron gas (2 DEG) region, satisfying demands of high power/frequency devices. In addition to HEMTs, examples of devices having heterostructures further include heterojunction bipolar transistors (HBT), heterojunction field effect transistor (HFET), and modulation-doped FETs (MODFET).

### SUMMARY OF THE DISCLOSURE

In accordance with one aspect of the present disclosure, a semiconductor device is provided. The semiconductor device includes a first III-V nitride-based layer, a second III-V nitride-based layer, a nitride-based semiconductor layer, and a nitride-based transistor. The first III-V nitride-based layer is disposed over a substrate by applying a first V/III ratio. The first III-V nitride-based layer has a first concentration of a group III element. The second III-V nitride-based layer is disposed on the first III-V nitride-based layer by applying a second V/III ratio less than the first V/III ratio. The second III-V nitride-based layer has a second concentration of the group III element less than the first concentration. The second concentration decreases along a direction away from the first III-V nitride-based layer, such that a first variance in the first concentration is less than a second variance in the second concentration. The nitride-based semiconductor layer is disposed over the second III-V nitride-based layer. The nitride-based transistor is disposed over the nitride-based semiconductor layer.

In accordance with one aspect of the present disclosure, a method for manufacturing a semiconductor device is provided. The method includes steps as follows. A first III-V nitride-based layer is formed over a substrate by applying a first V/III ratio. A second III-V nitride-based layer is formed on the first III-V nitride-based layer by applying a second V/III ratio less than the first V/III ratio. Change from the first V/III ratio to the second V/III ratio is continuous, such that a first concentration of a group III element of the first III-V nitride-based layer is greater a second concentration of the group III element of the second III-V nitride-based layer. A first variance in the first concentration is less than a second variance in the second concentration. A nitride-based semiconductor layer is formed over the second III-V nitride-based layer. A nitride-based transistor is formed over the nitride-based semiconductor layer.

In accordance with one aspect of the present disclosure, a nitride-based semiconductor device is provided. The nitride-based semiconductor device includes a first III-V nitride-based layer, a second III-V nitride-based layer, a nitride-based semiconductor layer, and a nitride-based transistor. The first III-V nitride-based layer is disposed over a substrate by applying a first V/III ratio. The first III-V nitride-based layer has a first concentration of a group III element. The second III-V nitride-based layer is disposed on the first III-V nitride-based layer by applying a second V/III ratio less than the first V/III ratio. The second III-V nitride-based layer has a second concentration of the group III element less than the first concentration, wherein the second concentration decreases along a direction away from the first III-V nitride-based layer. A degree of change in the second concentration per unit thickness within the second III-V nitride-based layer is greater than a degree of change in the first concentration per unit thickness within the first III-V nitride-based layer. A nitride-based semiconductor layer is disposed over the second III-V nitride-based layer. The nitride-based transistor is disposed over the nitride-based semiconductor layer.

By the above configuration, the buffer layer can be formed with the sub-III-V nitride-based layers thereof growing in different V/III ratios. The bottom portion of the buffer layer can be formed by applying the high III-V ratio, and the top portion of the buffer layer can be formed by applying the low III-V ratio. As such, the bottom portion of the buffer layer can reduce cracks inside the structure, and the top portion of the buffer layer can grow for curing the surface defeat of the bottom portion of the buffer layer. Moreover, such the III-V ratio arrangement can make the buffer layer have a condition for growing the channel layer.

### BRIEF DESCRIPTION OF THE DRAWINGS

Aspects of the present disclosure are readily understood from the following detailed description when read with the accompanying figures. It should be noted that various features may not be drawn to scale. That is, the dimensions of the various features may be arbitrarily increased or reduced for clarity of discussion. Embodiments of the present disclosure are described in more detail hereinafter with reference to the drawings, in which:

FIG. 1A is a vertical view of a semiconductor device according to some embodiments of the present disclosure;

FIG. 1B shows a graph of element concentration versus thickness of the buffer layer according to some embodiments of the present disclosure;

FIG. 2 is a vertical cross-sectional view of a semiconductor device according to some embodiments of the present disclosure;

FIG. 3 shows a graph of element concentration versus thickness of a buffer layer of a semiconductor device according to some embodiments of the present disclosure; and

FIG. 4 shows a graph of element concentration versus thickness of a buffer layer of a

semiconductor device according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

Spatial descriptions, such as “on,” “above,” “below,” “up,” “left,” “right,” “down,” “top,” “bottom,” “vertical,” “horizontal,” “side,” “higher,” “lower,” “upper,” “over,” “under,” and so forth, are specified with respect to a certain component or group of components, or a certain plane of a component or group of components, for the orientation of the component(s) as shown in the associated figure. It should be understood that the spatial descriptions used herein are for purposes of illustration only, and that practical implementations of the structures described herein can be spatially arranged in any orientation or manner, provided that the merits of embodiments of this disclosure are not deviated from by such arrangement.

Further, it is noted that the actual shapes of the various structures depicted as approximately rectangular may, in actual device, be curved, have rounded edges, have somewhat uneven thicknesses, etc. due to device fabrication conditions. The straight lines and right angles are used solely for convenience of representation of layers and features.

In the following description, semiconductor devices/dies/packages, methods for manufacturing the same, and the likes are set forth as preferred examples. It will be apparent to those skilled in the art that modifications, including additions and/or substitutions may be made without departing from the scope and spirit of the present disclosure. Specific details may be omitted so as not to obscure the present disclosure; however, the disclosure is written to enable one skilled in the art to practice the teachings herein without undue experimentation.

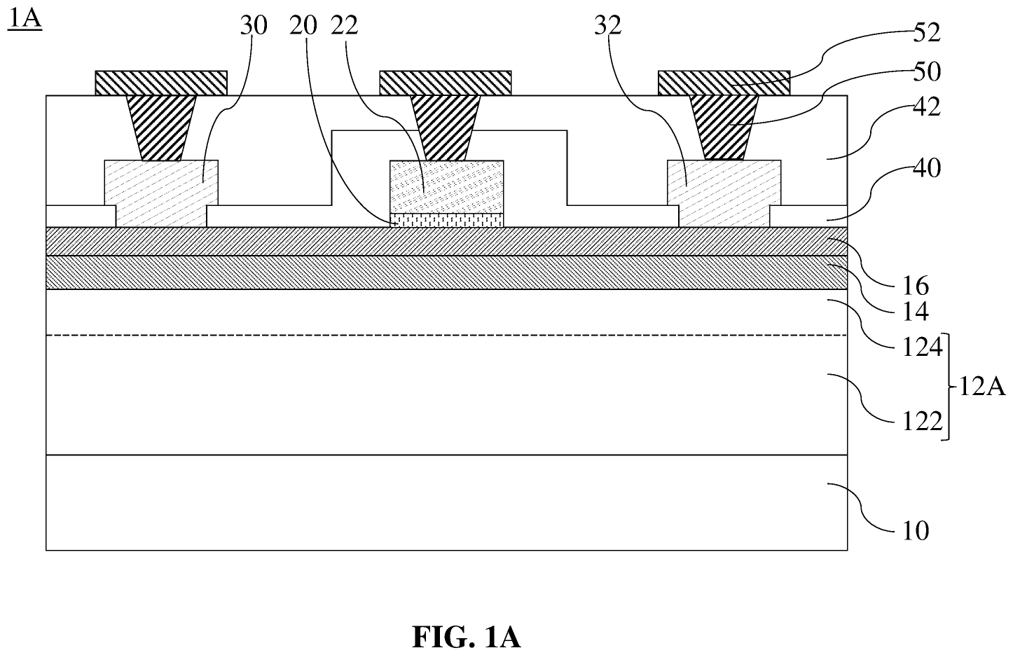

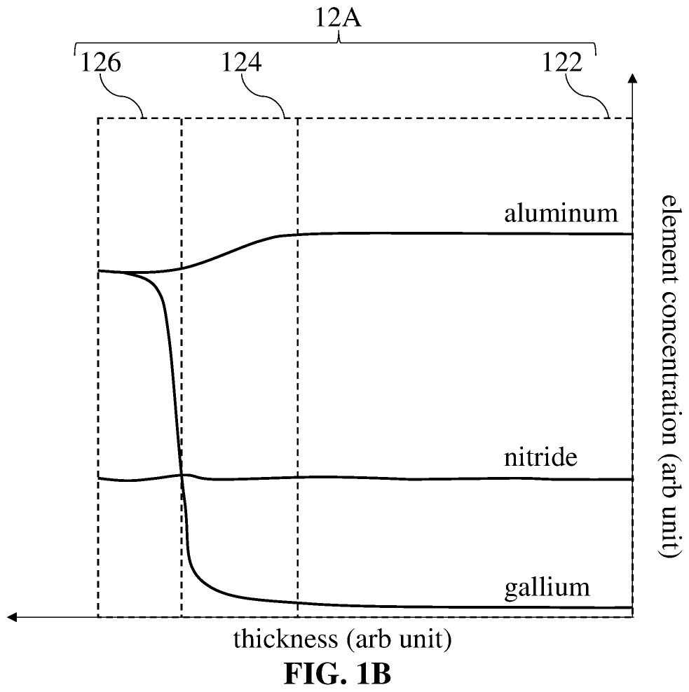

FIG. 1A is a vertical view of a semiconductor device 1A according to some embodiments of the present disclosure. The nitride-based semiconductor device 1A includes a substrate 10, a buffer layer 12A, nitride-based semiconductor layers 14, 16, a doped nitride-based semiconductor layer 20, a gate electrode 22, electrodes 30 and 32, passivation layers 40 and 42, contact vias 50, and a patterned conductive layer 52.

The substrate 10 may be a semiconductor substrate. The exemplary materials of the substrate 10 can include, for example but are not limited to, Si, SiGe, SiC, gallium arsenide, p-doped Si, n-doped Si, sapphire, semiconductor on insulator, such as silicon on insulator (SOI), or other suitable substrate materials. In some embodiments, the substrate 10 can include, for example, but is not limited to, group III elements, group IV elements, group V elements, or combinations thereof (e.g., III-V compounds). In other embodiments, the substrate 10 can include, for example but is not limited to, one or more other features, such as a doped region, a buried layer, an epitaxial (epi) layer, or combinations thereof.

The buffer layer 12A can be disposed on/over/above the substrate 10. The buffer layer 12A can be disposed between the substrate 10 and the nitride-based semiconductor layer 14. The buffer layer 12A can be configured to reduce lattice and thermal mismatches between the substrate 10 and the nitride-based semiconductor layer 14, thereby curing defects due to the mismatches/difference. The buffer layer 12A may include a III-V compound. The III-V compound can include, for example but are not limited to, aluminum, gallium, indium, nitrogen, or combinations thereof. Accordingly, the exemplary materials of the buffer layer can further include, for example but are not limited to, GaN, AlN, AlGaN, InAlGaN, or combinations thereof.

In some embodiments, the semiconductor device 1A may further include a nucleation layer (not shown). The nucleation layer may be formed between the substrate 10 and the buffer layer 12A. The nucleation layer can be configured to provide a transition to accommodate a mismatch/difference between the substrate 10 and a III-nitride layer of the buffer layer 12A. The exemplary material of the nucleation layer can include, for example but is not limited to AIN or any of its alloys.

The buffer layer 12A will dominate the performance of the nitride-based semiconductor device 1A. The quality of the buffer layer 12A will dominate the growth quality for an epitaxial layer to be formed on the buffer layer 12A, such as channel layer. In addition, low quality of a buffer layer will result in cracks formed into structure.

Accordingly, in the present disclosure, a buffer layer with quality improved is provided.

The buffer layer 12A includes III-V nitride-based layers 122 and 124. The III-V nitride-based layer 122 is disposed over the substrate 10. The III-V nitride-based layer 124 is disposed on the III-V nitride-based layer 122. The III-V nitride-based layer 124 is disposed between the III-V nitride-based layer 122 and the nitride-based semiconductor layer 14. The III-V nitride-based layer 122 is in contact with the III-V nitride-based layer 124.

In some embodiments, the III-V nitride-based layers 122 and 124 are merged with each other so no visible interface is formed therebetween. In some embodiments, the III-V nitride-based layers 122 and 124 are connected with each other with a visible interface formed therebetween.

The III-V nitride-based layer 122 is formed by applying a first V/III ratio to its growth. The III-V nitride-based layer 124 is formed by applying a second V/III ratio to its growth. In some embodiments, the V/III ratio includes V/III flux ratio during epitaxial growth. The second V/III ratio of the III-V nitride-based layer 124 is less than the first V/III ratio of the III-V nitride-based layer 122. The difference at the first and second V/III ratios will result in different growth quality.

In this regard, when a layer is formed by using epitaxial growth in a low V/III ratio, longitudinal growth is much different than lateral growth, which results in compensation for surface morphology. When a layer is formed by using epitaxial growth in a high V/III ratio, the layer tends to grow as epitaxial island growth, so the growth is performed as “three-dimensional growth”, which means the difference between longitudinal growth and lateral growth is less than that in the low V/III ratio. Such the epitaxial growth in a high V/III ratio can suppress cracks in the formed layer. However, epitaxial growth in a high V/III ratio will impact to surface morphology.

In the buffer layer 12A, the III-V nitride-based layer 122 with the higher V/III ratio is configured to serve as a bottom portion of the buffer layer 12A, and the III-V nitride-based layer 124 with the lower V/III ratio is configured to serve as a top portion of the buffer layer 12A. The III-V nitride-based layer 122 with the higher V/III ratio can build high structural quality. The III-V nitride-based layer 124 with the lower V/III ratio can be formed to compensate higher surface roughness of the III-V nitride-based layer 122. Accordingly, the growth quality of the buffer layer 12A can get improved.

In some embodiments, a high V/III ratio is defined as being equal to or greater than about 7000. In some embodiments, a high V/III ratio is defined as being in a range from about 7000 to about 10000. In some embodiments, a low V/III ratio is defined as being equal to or less than about 200. In some embodiments, a low V/III ratio is defined as being in a range from about 10 to about 200.

In some embodiments, to improve the yield rate and the reliability, the III-V nitride-based layer 122 can be formed to as being thicker than the III-V nitride-based layer 124. In some embodiments, the III-V nitride-based layer 122 has a thickness greater than a thickness of the III-V nitride-based layer 124.

Also, such the configuration can lead element concentration into a compatible condition for growing a channel layer. For a high-electron-mobility transistor (HEMT) device, a channel layer is formed from III-V material. For example, a channel layer may be formed from gallium nitride (GaN) and be devoid of aluminum. To match the composition of the channel layer, a buffer layer beneath the channel layer is better to have gradually decreasing aluminum concentration.

In some embodiments, each of the III-V nitride-based layers includes aluminum nitride (AlN). In some embodiments, minute amount of impurity of gallium can be added into at least one of the III-V nitride-based layers.

FIG. 1B shows a graph of element concentration versus thickness of the buffer layer 12A according to some embodiments of the present disclosure. The X-axis represents the upward position (i.e., distance/thinness/depth) from the substrate 10 with arb unit. The Y-axis represents element concentration with arb unit. Aluminum, nitride, and gallium concentrations are listed in the graph.

The III-V nitride-based layer 122 has a group III element and a group V element. Accordingly, the III-V nitride-based layer 122 has an aluminum concentration, a nitride concentration, a gallium concentration. The III-V nitride-based layer 124 has a group III element and a group V element. Accordingly, the III-V nitride-based layer 124 has an aluminum concentration, a nitride concentration, a gallium concentration.

The aluminum concentration of the III-V nitride-based layer 122 is greater than the aluminum concentration of the III-V nitride-based layer 124. The average aluminum concentration of the III-V nitride-based layer 122 is greater than the average aluminum concentration of the III-V nitride-based layer 124.

The aluminum concentration of the III-V nitride-based layer 122 is in uniform trend. The aluminum concentration of the III-V nitride-based layer 124 decreases along a direction away from the III-V nitride-based layer 122. Therefore, a variance in the aluminum concentration of the III-V nitride-based layer 122 is less than a variance in the aluminum concentration of the III-V nitride-based layer 124.

More specifically, the aluminum concentration of the III-V nitride-based layer 122 is high with respect to the aluminum concentration of the III-V nitride-based layer 124. As the aluminum concentration of the III-V nitride-based layer 122 is greater than the aluminum concentration of the III-V nitride-based layer 124, the aluminum concentration of the III-V nitride-based layer 124 can change from high to low. Regarding the change from high to low, the aluminum concentration of the III-V nitride-based layer 124 may strictly decrease along the direction away from the III-V nitride-based layer 122. Furthermore, a curve of change in the aluminum concentration of the III-V nitride-based layer 124 per unit thickness the III-V nitride-based layer 124 is continuous.

In some embodiment, the aluminum concentration of the III-V nitride-based layer 122 is about uniform, which means there may be a slight fluctuation in the aluminum concentration of the III-V nitride-based layer 122. Even though a slight fluctuation occurs, a biggest difference of the aluminum concentration of the III-V nitride-based layer 122 within the thickness of the III-V nitride-based layer 122 is still less than a biggest difference of the aluminum concentration of the III-V nitride-based layer 124 within the thickness of the III-V nitride-based layer 124. Herein, the biggest difference means a difference between the maximum and minimum values of the corresponding element concentration.

In the III-V nitride-based layer 124, the aluminum concentration varies in different gradients. More specifically, a degree of change in the aluminum concentration of the III-V nitride-based layer 124 per unit thickness within the III-V nitride-based layer 124 varies. Correspondingly, a degree of change in the aluminum concentration of the III-V nitride-based layer of 124 per unit thickness within the III-V nitride-based layer 124 is greater than a degree of change in the aluminum concentration of the III-V nitride-based layer 122 per unit thickness within the III-V nitride-based layer 122.

In some embodiments, during the growth of the III-V nitride-based layer 124, the aluminum concentration can be altered at the low V/III ratio condition. As a result, the III-V nitride-based layer 124 has a top portion and a bottom portion further away from the III-V nitride-based layer 122 than the top portion. The top portion is located between the III-V nitride-based layer 124 and the bottom portion. A degree of change in the aluminum concentration of the III-V nitride-based layer of 124 per unit thickness within the top portion is smoother than a degree of change in the aluminum concentration of the III-V nitride-based layer of 124 per unit thickness within the bottom portion.

Such the configuration is made for letting the buffer later 120 match a condition for channel layer growth, and the combination of the high and low V/III ratio can improve the film quality of the buffer later 120.

In some embodiments, the buffer layer 120 may further include a Ga-based transition layer 126. The Ga-based transition layer 126 is disposed on the III-V nitride-based layers 122 and 124. The Ga-based transition layer 126 is disposed on the III-V nitride-based layers 122 and 124. The Ga-based transition layer 126 is in contact with the III-V nitride-based layer 124. The Ga-based transition layer 126 has a gallium concentration that increases along a direction away from the III-V nitride-based layers 122 and 124. The increasing in the gallium concentration is made for matching a condition for channel layer growth. Furthermore, the Ga-based transition layer 126 has an aluminum concentration that decreases along a direction away from the III-V nitride-based layers 122 and 124.

Referring to FIG. 1A again, the nitride-based semiconductor layer 14 can be disposed on/over/above the buffer layer 12A. The nitride-based semiconductor layer 14 can make contact with the buffer layer 12A. The nitride-based semiconductor layer 16 can be disposed on/over/above the nitride-based semiconductor layer 14. The exemplary materials of the nitride-based semiconductor layer 14 can include, for example but are not limited to, nitrides or group III-V compounds, such as GaN, AlN, InN, InxAlyGa_{(1-x-y)}N where x+y≤1, AlyGa^{(1-y)}N where y≤1. The exemplary materials of the nitride-based semiconductor layer 16 can include, for example but are not limited to, nitrides or group III-V compounds, such as GaN, AlN, InN, InxAlyGa_{(1-x-y)}N where x+y≤1, AlyGa_{(1-y)}N where y≤1.

The exemplary materials of the nitride-based semiconductor layers 14 and 16 are selected such that the nitride-based semiconductor layer 16 has a bandgap (i.e., forbidden band width) greater/higher than a bandgap of the nitride-based semiconductor layer 14, which causes electron affinities thereof different from each other and forms a heterojunction therebetween. For example, when the nitride-based semiconductor layer 14 is an undoped GaN layer having a bandgap of approximately 3.4 eV, the nitride-based semiconductor layer 16 can be selected as an AlGaN layer having bandgap of approximately 4.0 eV. As such, the nitride-based semiconductor layers 14 and 16 can serve as a channel layer and a barrier layer, respectively. A triangular well potential is generated at a bonded interface between the channel and barrier layers, so that electrons accumulate in the triangular well, thereby generating a two-dimensional electron gas (2 DEG) region adjacent to the heterojunction. Accordingly, the semiconductor device 1A is available to include at least one GaN-based high-electron-mobility transistor (HEMT).

A nitride-based transistor can be disposed over the nitride-based semiconductor layers 14 and 16. The nitride-based transistor can be constituted by the doped nitride-based semiconductor layer 20, the gate electrode 22, and the electrodes 30 and 32

The doped nitride-based semiconductor layer 20 and the gate electrode 22 are stacked on the nitride-based semiconductor layer 16. The doped nitride-based semiconductor layer 20 is between the nitride-based semiconductor layer 16 and the gate electrode 22.

The semiconductor device 1A can be designed as being an enhancement mode device, which is in a normally-off state when the gate electrode 22 is at approximately zero bias. Specifically, the doped nitride-based semiconductor layer 20 creates a p-n junction with the nitride-based semiconductor layer 14 to deplete the 2 DEG region, such that a zone of the 2 DEG region corresponding to a position below the gate electrode 22 has different characteristics (e.g., different electron concentrations) than the rest of the 2 DEG region and thus is blocked. Due to such mechanism, the semiconductor device 1A has a normally-off characteristic. In other words, when no voltage is applied to the gate electrode 22 or a voltage applied to the gate electrode 22 is less than a threshold voltage (i.e., a minimum voltage required to form an inversion layer below the gate electrode 22), the zone of the 2 DEG region below the gate electrode 22 is kept blocked, and thus no current flows therethrough. Moreover, by providing the doped nitride-based semiconductor layer 20, gate leakage current is reduced and an increase in the threshold voltage during the off-state is achieved.

In some embodiments, the doped nitride-based semiconductor layer 20 can be omitted, such that the semiconductor device 1A is a depletion-mode device, which means the semiconductor device 1A in a normally-on state at zero gate-source voltage.

The exemplary materials of the doped nitride-based semiconductor layer 20 can include, for example but are not limited to, p-doped group III-V nitride semiconductor materials, such as p-type GaN, p-type AlGaN, p-type InN, p-type AlInN, p-type InGaN, p-type AlInGaN, or combinations thereof. In some embodiments, the p-doped materials are achieved by using a p-type impurity, such as Be, Mg, Zn, Cd. In some embodiments, the nitride-based semiconductor layer 14 includes undoped GaN and the nitride-based semiconductor layer 16 includes AlGaN, and the doped nitride-based semiconductor layer 20 is a p-type GaN layer which can bend the underlying band structure upwards and to deplete the corresponding zone of the 2 DEG region, so as to place the semiconductor device 1A into an off-state condition.

In some embodiments, the gate electrode 22 may include metals or metal compounds. The exemplary materials of the metals or metal compounds can include, for example but are not limited to, W, Au, Pd, Ti, Ta, Co, Ni, Pt, Mo, TiN, TaN, metal alloys thereof, or other metallic compounds. In some embodiments, the exemplary materials of the gate electrode 22 may include, for example but are not limited to, nitrides, oxides, silicides, doped semiconductors, or combinations thereof. In some embodiments, the optional dielectric layer can be formed by a single layer or more layers of dielectric materials. The exemplary dielectric materials can include, for example but are not limited to, one or more oxide layers, a SiOx layer, a SiNx layer, a high-k dielectric material (e.g., HfO₂, Al₂O₃, TiO₂, HfZrO, Ta₂O₃, HfSiO₄, ZrO₂, ZrSiO₂, etc), or combinations thereof.

The passivation layer 40 is disposed over the nitride-based semiconductor layer 16. The passivation layer 40 covers the gate structure 124 for a protection purpose. The exemplary materials of the passivation layer 40 can include, for example but are not limited to, SiNx, SiOx, SiON, SiC, SiBN, SiCBN, oxides, nitrides, or combinations thereof. In some embodiments, the passivation layer 40 is a multi-layered structure, such as a composite dielectric layer of Al₂O₃/SiN, Al₂O₃/SiO₂, AlN/SiN, AlN/SiO₂, or combinations thereof.

The electrodes 30 and 32 are disposed on the nitride-based semiconductor layer 16. The electrodes 30 and 32 are located at two opposite sides of the gate electrode 22 (i.e., the gate electrode 22 is located between the electrodes 30 and 32). The gate electrode 22 and the electrodes 30 and 32 can collectively act as a GaN-based HEMT with the 2 DEG region.

The electrodes 30 and 32 have bottom portions penetrating the passivation layer 40 to form interfaces with the nitride-based semiconductor layer 16. The electrodes 30 and 32 have top portions wider than the bottom portions thereof. The top portions of the electrodes 30 and 32 extend over portions of the passivation layer 40.

In some embodiments, each of the electrodes 30 and 32 includes one or more conformal conductive layers. In some embodiments, the electrodes 30 and 32 can include, for example but are not limited to, metals, alloys, doped semiconductor materials (such as doped crystalline silicon), other conductor materials, or combinations thereof. The exemplary materials of the electrodes 30 and 32 can include, for example but are not limited to, Ti, AlSi, TiN, or combinations thereof. In some embodiments, each of the electrodes 30 and 32 forms ohmic contact with the nitride-based semiconductor layer 16. The ohmic contact can be achieved by applying Ti, Al, or other suitable materials for the electrodes 30 and 32.

The passivation layer 42 is disposed above the passivation layer 40 and the electrodes 30 and 32. The passivation layer 42 covers the GaN-based HEMT. The passivation layer 42 covers the electrodes 30 and 32. The passivation layer 42 may have a flat topmost surface, which is able to act as a flat base for carrying layers formed in a step subsequent to the formation thereof. The exemplary materials of the passivation layer 42 can include, for example but are not limited to, SiNx, SiOx, SiON, SiC, SiBN, SiCBN, oxides, nitrides, or combinations thereof. In some embodiments, the passivation layer 42 is a multi-layered structure, such as a composite dielectric layer of Al₂O₃/SiN, Al₂O₃/SiO₂, AlN/SiN, AlN/SiO₂, or combinations thereof.

The contact vias 50 penetrate the passivation layer 42 to connect to the gate electrode 22 and the electrodes 30 and 32. The contact vias 50 form interfaces with the gate electrode 22 and the electrodes 30 and 32. The exemplary materials of the contact vias 50 can include, for example but are not limited to, Cu, Al, or combinations thereof.

The patterned conductive layer 52 is disposed on the passivation layer 42. The patterned conductive layer 52 has a plurality of metal lines over the gate electrode 22 and the electrodes 30 and 32 for the purpose of implementing interconnects between circuits. The metal lines are in contact with the contact vias 50, respectively, such that gate electrode 22 and the electrodes 30 and 32 can be arranged into a circuit. For example, the GaN-based HEMT can be electrically connected to other component(s) via the metal lines of the patterned conductive layer 52. In other embodiments, the patterned conductive layer 52 may include pads or traces for the same purpose.

To run a method for manufacturing the semiconductor device 1A, receipts for the growth of the buffer layer 120 can be turned. In the following descriptions, deposition techniques can include, for example but are not limited to, atomic layer deposition (ALD), physical vapor deposition (PVD), chemical vapor deposition (CVD), metal organic CVD (MOCVD), plasma enhanced CVD (PECVD), low-pressure CVD (LPCVD), plasma-assisted vapor deposition, epitaxial growth, or other suitable processes.

In the growth of the buffer layer 120, the III-V nitride-based layers 122 and 124 can be formed in the same chamber continuously. The growth of the buffer layer 120 can be achieved by deposition techniques.

During a deposition process for the growth of the buffer layer 120, aluminum, gallium, and nitrogen precursors are introduced into a gas flow in a chamber. The ratio among these elements correlates with elements concentration of the formed buffer layer 120. Different V/III ratio can be achieved by altering the ratio among these elements in the gas flow. As the ratio among these elements in the gas flow is altered for changing the V/III ratio from high to low, the aluminum concentration decreases as well. As such, the buffer layer 120 having the property as shown in the graph of FIG. 1B is obtained.

After the growth of the buffer layer 120, the nitride-based semiconductor layers 14 and 16 are formed over the III-V nitride-based layer 124 of the buffer layer 120 in sequence. Thereafter, the nitride-based transistor at least including the gate electrode 22 and the electrodes 30 and 32 is formed over the nitride-based semiconductor layers 14 and 16.

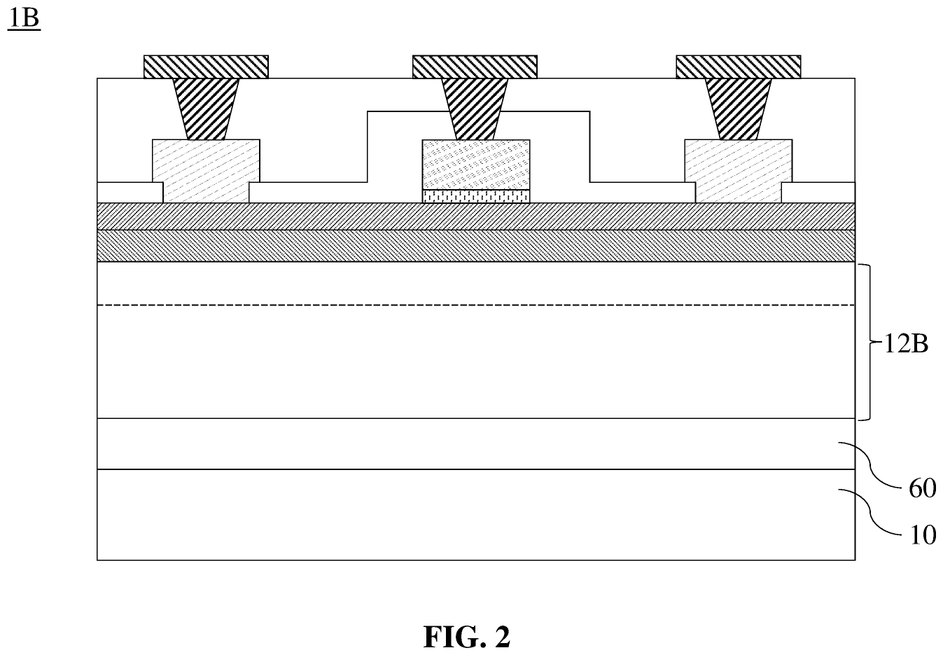

FIG. 2 is a vertical cross-sectional view of a semiconductor device 1B according to some embodiments of the present disclosure. The semiconductor device 1B is similar to the semiconductor device 1A as described and illustrated with reference to FIG. 1A, except that the semiconductor device 1B further includes an interlayer layer 60. The interlayer layer 60 is located between the substrate 10 and the buffer layer 12B. The interlayer layer 60 can serve as a nucleation layer. The interlayer layer 60 can be configured to provide a transition to accommodate a mismatch/difference between the substrate 10 the buffer layer 12B. The exemplary material of the nucleation layer can include, for example but is not limited to AlN or any of its alloys.

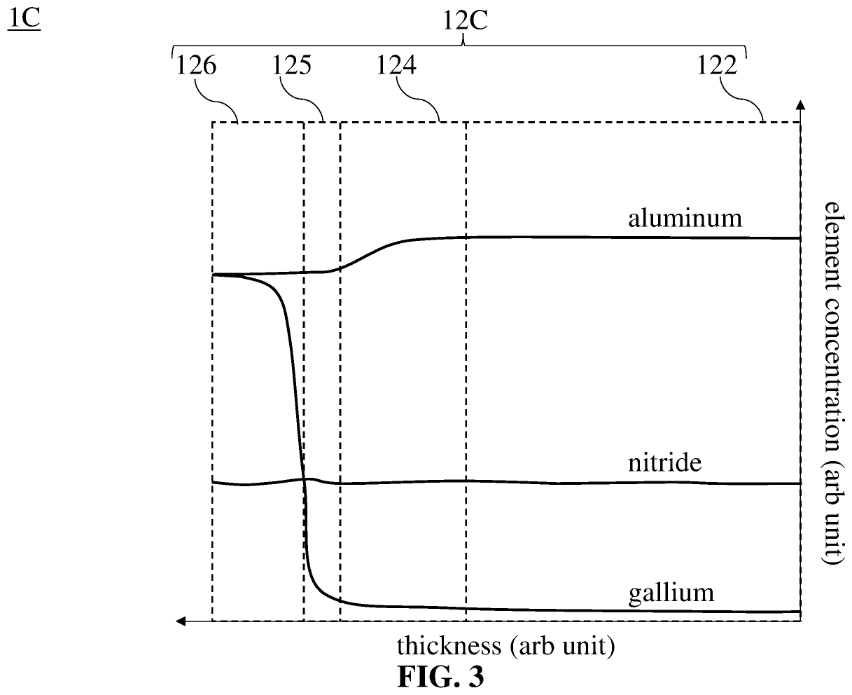

FIG. 3 shows a graph of element concentration versus thickness of a buffer layer 12C of a semiconductor device 1C according to some embodiments of the present disclosure. The X-axis represents the upward position (i.e., distance/thinness/depth) as the previous stated with arb unit. The Y-axis represents element concentration with arb unit. Aluminum, nitride, and gallium concentrations are listed in the graph. The semiconductor device 1C is similar to the semiconductor device 1A as described and illustrated with reference to FIG. 1A, except that the buffer layer 120C further includes a III-V nitride-based layer 125.

The III-V nitride-based layer 125 can be disposed between the III-V nitride-based layer 124 and the nitride-based semiconductor layer (e.g., the nitride-based semiconductor layer 14 or 16 as shown in FIG. 1A). The III-V nitride-based layer 125 can be disposed between the III-V nitride-based layer 124 and the Ga-based transition layer 126. The III-V nitride-based layer 125 is formed by applying a V/III ratio less than the V/III ratio of the III-V nitride-based layer 122. In some embodiments, the V/III ratio of the III-V nitride-based layer 125 is less than the V/III ratio of the III-V nitride-based layer 124.

The III-V nitride-based layer 125 has an aluminum concentration less than the aluminum concentration of the III-V nitride-based layer 122. The average aluminum concentration of the III-V nitride-based layer 125 is less than the average aluminum concentration of the III-V nitride-based layer 122. The aluminum concentration of the III-V nitride-based layer 125 is less than the aluminum concentration of the III-V nitride-based layer 124. The average aluminum concentration of the III-V nitride-based layer 125 is less than the average aluminum concentration of the III-V nitride-based layer 124.

The III-V nitride-based layer 125 can be configured to buffer the change in the buffer layer 12C. In some embodiments, as the V/III ratio of the III-V nitride-based layer 124 changes from high to low, the process recipe is changed with the real time. The “V/III ratio changed with the real time” may be more unstable than the uniform V/III ratio in the process. To improve the film quality of the buffer layer 12C after the growth of the III-V nitride-based layer 124, the III-V nitride-based layer 125 can be formed by using recipes of a uniform low V/III ratio. Accordingly, a variance in the aluminum concentration of the III-V nitride-based layer 125 is less than the variance in the aluminum concentration of the III-V nitride-based layer 124. More specifically, a degree of change in the aluminum concentration of the III-V nitride-based layer 124 per unit thickness within the III-V nitride-based layer 124 is greater than a degree of change in the aluminum concentration of the III-V nitride-based layer 125 per unit thickness within the III-V nitride-based layer 125.

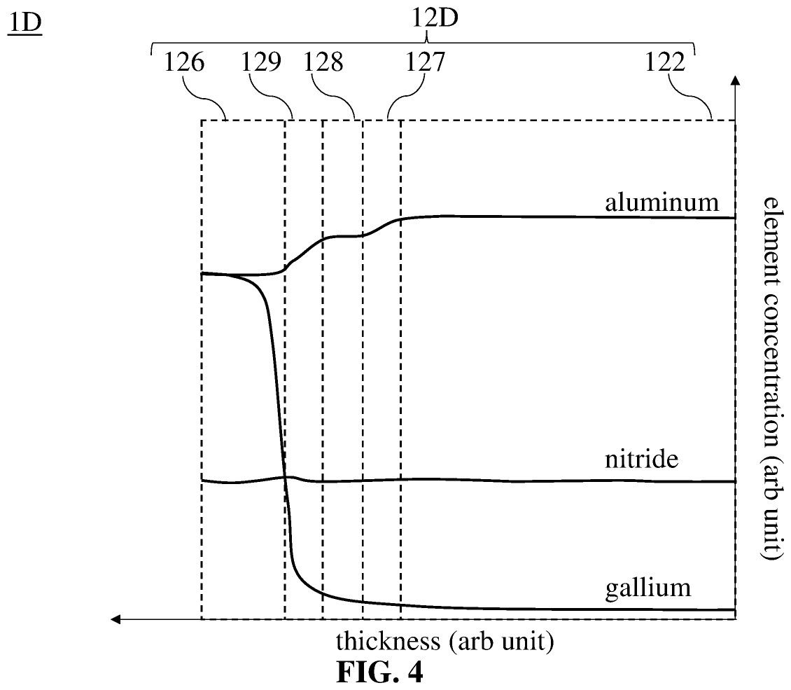

FIG. 4 shows a graph of element concentration versus thickness of a buffer layer 12D of a semiconductor device 1D according to some embodiments of the present disclosure. The X-axis represents the upward position (i.e., distance/thinness/depth) as the previous stated with arb unit. The Y-axis represents element concentration with arb unit. Aluminum, nitride, and gallium concentrations are listed in the graph. The semiconductor device 1D is similar to the semiconductor device 1A as described and illustrated with reference to FIG. 1A, except that the buffer layer 120C further includes III-V nitride-based layers 127, 128, and 129. The III-V nitride-based layer 124 is omitted in this embodiment.

The III-V nitride-based layers 127, 128, and 129 can be disposed between the III-V nitride-based layer 122 and the nitride-based semiconductor layer (e.g., the nitride-based semiconductor layer 14 or 16 as shown in FIG. 1A). The III-V nitride-based layers 127, 128, and 129 can be disposed between the III-V nitride-based layer 122 and the Ga-based transition layer 126. The III-V nitride-based layers 127, 128, and 129 can be formed on the III-V nitride-based layer 124 in sequence.

The III-V nitride-based layer 128 is formed by applying a V/III ratio less than the V/III ratio of the III-V nitride-based layer 122. The III-V nitride-based layer 128 is formed by applying a V/III ratio equal to or less than the V/III ratio of the III-V nitride-based layer 128. The III-V nitride-based layer 129 is formed by applying a V/III ratio less than the V/III ratio of the III-V nitride-based layer 128.

The III-V nitride-based layer 127 has an aluminum concentration less than the aluminum concentration of the III-V nitride-based layer 122. The average aluminum concentration of the III-V nitride-based layer 127 is less than the average aluminum concentration of the III-V nitride-based layer 122. The III-V nitride-based layer 128 has an aluminum concentration less than the aluminum concentration of the III-V nitride-based layer 127. The average aluminum concentration of the III-V nitride-based layer 128 is less than the average aluminum concentration of the III-V nitride-based layer 127. The III-V nitride-based layer 129 has an aluminum concentration less than the aluminum concentration of the III-V nitride-based layer 128. The average aluminum concentration of the III-V nitride-based layer 129 is less than the average aluminum concentration of the III-V nitride-based layer 128.

The III-V nitride-based layer 128 can be configured to buffer the change in the buffer layer 12D. The V/III ratio of the III-V nitride-based layers 127 and 129 can changes from high to low. The III-V nitride-based layer 128 can be formed by using recipes of a V/III ratio more uniform than those of the III-V nitride-based layers 127 and 129. The growth of the III-V nitride-based layer 128 can enhance the entire stability of the formation of the buffer layer 12D. That is, in the present embodiment, the V/III ratio of the buffer layer 12D changes as staged adjustment, which can reduce the process variation.

By the above configuration, the buffer layer can be formed with the sub-III-V nitride-based layers thereof growing in different V/III ratios. The bottom portion of the buffer layer can be formed by applying the high III-V ratio, and the top portion of the buffer layer can be formed by applying the low III-V ratio. As such, the bottom portion of the buffer layer can reduce cracks inside the structure, and the top portion of the buffer layer can grow for curing the surface defeat of the bottom portion of the buffer layer. Moreover, such the III-V ratio arrangement can make the buffer layer have a condition for growing the channel layer.

The embodiments were chosen and described in order to best explain the principles of the disclosure and its practical application, thereby enabling others skilled in the art to understand the disclosure for various embodiments and with various modifications that are suited to the particular use contemplated.

As used herein and not otherwise defined, the terms “substantially,” “substantial,” “approximately” and “about” are used to describe and account for small variations. When used in conjunction with an event or circumstance, the terms can encompass instances in which the event or circumstance occurs precisely as well as instances in which the event or circumstance occurs to a close approximation. For example, when used in conjunction with a numerical value, the terms can encompass a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. The term “substantially coplanar” can refer to two surfaces within micrometers of lying along a same plane, such as within 40 μm, within 30 μm, within 20 μm, within 10 μm, or within 1 μm of lying along the same plane.

As used herein, the singular terms “a,” “an,” and “the” may include plural referents unless the context clearly dictates otherwise. In the description of some embodiments, a component provided “on” or “over” another component can encompass cases where the former component is directly on (e.g., in physical contact with) the latter component, as well as cases where one or more intervening components are located between the former component and the latter component.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not necessarily be drawn to scale. There may be distinctions between the artistic renditions in the present disclosure and the actual apparatus due to manufacturing processes and tolerances. Further, it is understood that actual devices and layers may deviate from the rectangular layer depictions of the FIGS. and may include angles surfaces or edges, rounded corners, etc. due to manufacturing processes such as conformal deposition, etching, etc. There may be other embodiments of the present disclosure which are not specifically illustrated. The specification and the drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations.

1. A nitride-based semiconductor device comprising:
a first III-V nitride-based layer disposed over a substrate by applying a first V/III ratio, wherein the first III-V nitride-based layer has a first concentration of a group III element;
a second III-V nitride-based layer disposed on the first III-V nitride-based layer by applying a second V/III ratio less than the first V/III ratio, wherein the second III-V nitride-based layer has a second concentration of the group III element less than the first concentration, wherein the second concentration decreases along a direction away from the first III-V nitride-based layer, and a first variance in the first concentration is less than a second variance in the second concentration;
a nitride-based semiconductor layer disposed over the second III-V nitride-based layer; and
a nitride-based transistor disposed over the nitride-based semiconductor layer.

2. The nitride-based semiconductor device of claim 1, wherein a degree of change in the second concentration per unit thickness within the second III-V nitride-based layer varies.

3. The nitride-based semiconductor device of claim 1, wherein the second III-V nitride-based layer has a first portion and a second portion further away from the first III-V nitride-based layer than the first portion, and a degree of change in the second concentration per unit thickness within the first portion is smoother than a degree of change in the second concentration per unit thickness within the second portion.

4. The nitride-based semiconductor device of claim 1, wherein a degree of change in the second concentration per unit thickness within the second III-V nitride-based layer is greater than a degree of change in the first concentration per unit thickness within the first III-V nitride-based layer.

5. The nitride-based semiconductor device of claim 1, wherein the second concentration gradually changes from high to low, and a curve of change in the second concentration per unit thickness within the second III-V nitride-based layer is continuous.

6. The nitride-based semiconductor device of claim 1, wherein a biggest difference of the first concentration within the thickness of the first III-V nitride-based layer is less than a biggest difference of the second concentration within the thickness of the second III-V nitride-based layer.

7. The nitride-based semiconductor device of claim 1, the first V/III ratio is equal to or greater than 7000.

8. The nitride-based semiconductor device of claim 1, the second V/III ratio is equal to or less than 200.

9. The nitride-based semiconductor device of claim 1, further comprising:
a third III-V nitride-based layer between the second III-V nitride-based layer and the nitride-based semiconductor layer by applying a third V/III ratio less than the first V/III ratio, wherein the third III-V nitride-based layer has a third concentration of the group III element less than the first concentration, wherein a third variance in the third concentration is less than the second variance in the second concentration.

10. The nitride-based semiconductor device of claim 9, a degree of change in the second concentration per unit thickness within the second III-V nitride-based layer is greater than a degree of change in the third concentration per unit thickness within the third III-V nitride-based layer.

11. The nitride-based semiconductor device of claim 1, wherein the second concentration strictly decreases along the direction away from the first III-V nitride-based layer.

12. The nitride-based semiconductor device of claim 1, further comprising a Ga-based transition layer disposed on and in contact with the second III-V nitride-based layer, wherein the Ga-based transition layer has a gallium concentration increasing along a direction away from the second III-V nitride-based layer.

13. The nitride-based semiconductor device of claim 1, wherein the first III-V nitride-based layer has a thickness greater than a thickness of the second III-V nitride-based layer.

14. The nitride-based semiconductor device of claim 1, wherein each of the first III-V nitride-based layer and the second III-V nitride-based layer comprises aluminum nitride (AlN).

15. The nitride-based semiconductor device of claim 1, wherein the nitride-based semiconductor layer comprises gallium nitride (GaN), aluminum gallium nitride (AlGaN), or combinations thereof.

16. A method for manufacturing a nitride-based semiconductor device, comprising:
forming a first III-V nitride-based layer over a substrate by applying a first V/III ratio;
forming a second III-V nitride-based layer on the first III-V nitride-based layer by applying a second V/III ratio less than the first V/III ratio, wherein change from the first V/III ratio to the second V/III ratio is continuous, and a first concentration of a group III element of the first III-V nitride-based layer is greater a second concentration of the group III element of the second III-V nitride-based layer, and a first variance in the first concentration is less than a second variance in the second concentration;
forming a nitride-based semiconductor layer over the second III-V nitride-based layer; and
forming a nitride-based transistor over the nitride-based semiconductor layer.

17. The method of claim 16, the first V/III ratio is equal to or greater than 7000.

18. The method of claim 16, the second V/III ratio is equal to or less than 200.

19. The method of claim 16, wherein each of the first III-V nitride-based layer and the second III-V nitride-based layer comprises aluminum nitride (AlN).

20. The method of claim 16, wherein the nitride-based semiconductor layer comprises gallium nitride (GaN), aluminum gallium nitride (AlGaN), or combinations thereof.

21-25. (canceled)
